(19) United States
(12) Patent Application Publication
(10) Pub. No.: US 2012/0155038 A1
(43) Pub. Date: Jun. 21, 2012

(54) FLEXIBLE CIRCUIT BOARD AND MANUFACTURING METHOD THEREOF

(75) Inventors: Yasumori Fukushima, Osaka-shi (JP); Masaki Fujiwara, Osaka-shi (JP); Steven Roy Droes, Camas, WA (US)

(73) Assignee: SHARP KABUSHIKI KAISHA, Osaka-shi, Osaka (JP)

(21) Appl. No.: 13/392,247

(22) PCT Filed: Jul. 28, 2010
(86) PCT No.: PCT/JP2010/062719

§ 371 Date: Feb. 24, 2012

(30) Foreign Application Priority Data
Nov. 30, 2009 (JP) 2009-272740

(51) Int. Cl. H05K 1/02; H05K 3/20; H05K 3/00; H05K 1/18

(52) U.S. Cl. 361/750; 361/749; 29/831; 216/13

(57) ABSTRACT

The present invention provides a high-performance flexible circuit board having excellent flexibility, a fine wiring pattern, and fine electric contacts, and a manufacturing method thereof. In a flexible circuit board (20), a second insulating layer (24) made of an inorganic material is positioned between a wiring layer (25) and a first insulating layer (23) made of an inorganic material.

### TECHNICAL FIELD

The present invention relates to a flexible circuit board and a method for manufacturing the flexible circuit board. Specifically, the present invention relates to: a high-performance flexible circuit board with excellent flexibility, a fine wiring pattern, and fine electric contacts; and a method for manufacturing the flexible circuit board.

### BACKGROUND ART

Conventionally, there has been known an art that (i) mounts a semiconductor circuit element such as a silicon LSI (Large Scale Integrated Circuit), or a passive element such as resistor, capacitor, and inductor on or inside of a flexible board, and (ii) electrically connects them through wires (refer to the patent literatures 1 and 2 as examples).

A passive element is becoming smaller and smaller in size as required to meet a demand for high density mounting. Currently, the size of a passive element has been reduced to 1005 (1.0 mm×0.5 mm), 0603 (0.6 mm×0.3 mm) and 0402 (0.4 mm×0.2 mm), and is expected to be further reduced to 0201 (0.2 mm×0.1 mm). Since the size of a passive element mounted on a flexible board is 1 mm or less as above, the passive element hardly affects the flexibility of a flexible circuit board even if the passive element is a hard-constructed object.

On the other hand, a semiconductor circuit element such as an LSI is generally more than ten times bigger than a passive element, and has a variety of forms, such as square and rectangular. Depending on individual functions and circuit dimensions, semiconductor circuit elements vary in size from 1 square cm to 2 square cm, or even to bigger sizes. Because a semiconductor circuit element such as an LSI chip is made of a semiconductor material such as silicon, a semiconductor circuit element is hard, and the thickness of the board is normally around 600-800 μm. Therefore, thinning down the thickness of a board of a semiconductor circuit element mounted on a flexible board is a necessary step to achieve the flexibility of a flexible circuit board.

As a method for achieving the flexibility of a flexible circuit board, for example, the patent literature 1 discloses a configuration in which a flexible wiring section has an LSI chip therein. More specifically, the wiring section as shown in FIG. 5 is configured such that an LSI chip 82 and an insulating resin layer (ground board) 77 formed under the LSI chip 82 are positioned between a wiring layer 30 and a wiring layer 40, and the LSI chip 82 and the wiring layer 30 are connected through a gold bump 31 penetrating the insulating resin layer 77. Besides, the LSI chip 82 has flexibility by being 50 μm or less in thickness.

However, the thinned-down semiconductor circuit element (LSI chip etc.) as shown in FIG. 5 has such a weakness as being fragile and easily broken. In particular, in a case where the thinned-down semiconductor circuit element is mounted on a flexible ground board in such a manner that a metal bump is formed beforehand at a portion of wiring on the flexible circuit board which portion is to be electrically connected with a semiconductor circuit element and the thinned-down semiconductor circuit element is thermally pressed to the flexible ground board while facing down to be electrically connected, there is a possibility of breakage of the thinned-down semiconductor circuit element due to mechanical and thermal stress.

As a way of preventing breakage of a semiconductor circuit element, for example, the non-patent literature 1 discloses a method for attaching a thin semiconductor circuit element onto a flexible ground board while the semiconductor circuit element faces up and making holes for wiring connections from a top so as to form metal wiring, thereby avoiding utilizing of thermocompression to establish electric connections. This method allows mounting the thin semiconductor circuit element on the flexible board without breaking the semiconductor circuit element board. A flexible circuit board manufactured in such a way is shown in FIG. 6.

As shown in FIG. 6, a flexible circuit board 50 disclosed in the non-patent document 1 is configured such that: a semiconductor circuit element 52 is positioned on a flexible insulating board (ground board) 51 made of an organic material; an insulating layer 53 made of an organic material is positioned on both the semiconductor circuit element 52 and on portions of the board 51 where the semiconductor circuit element 52 is not positioned; and a wiring layer 55 is positioned on the insulating layer 53. The wiring layer 55 is electrically connected with the semiconductor circuit element 52 through conductive layers 56 formed by filling contact holes perforating through the insulating layer 53 with a conductive material. Further, a protective layer 58 can be positioned on the wiring layer 55 in order to protect the wiring layer 55.

### CITATION LIST

### Patent Literature 1

Japanese Patent Application Publication, Tokukai, No. 2005-26458 (Publication Date: Jan. 27, 2005)

### Patent Literature 2

Japanese Patent Application Publication, Tokukai, No. 2002-43506 (Publication Date: Feb. 8, 2002)

### Non-Patent Literature 1

Jonathan Govaerts, Wim Christiaens and Jan Vanfleteren, ┌SID 09 DIGEST┘, Society for Information Display, p. 202-205

### SUMMARY OF INVENTION

### Technical Problem

On the flexible circuit board as shown in FIG. 6, the processing of the wiring layer is performed by patterning the wiring in such a manner that copper foil or plating copper is attached onto a flexible substrate, resist is applied onto the copper foil or plating copper to form a pattern, and the copper foil or plating copper is subjected to wet etching with iron chloride, copper chloride, ammonium hydroxide aqueous solution etc. to form wiring.

In this instance, since the processing of the wiring layer is performed through wet etching, the etching of the layer runs towards both a depth direction and a surface direction, and it is difficult to control the processing size. Consequently, the processing size is generally in the order of several dozens of μm, and processing with the size of 10 μm or less is difficult.

Contact holes that connect wiring with a semiconductor circuit element/passive element are mechanically formed with a drill or when the contact holes are required to be smaller, the contact holes are formed by opening through-holes with excimer laser and YAG laser. However, the size of a through-hole that can be opened is normally about several dozens of μm, and it is difficult to make contact holes of 10 μm or less in size.

In a case of microfabrication of wiring layer and contact holes, such microfabrication is expected to be achieved through patterning by anisotropic dry etching with a photoresist as a mask.

However, a photoresist subjected to dry etching suffers a problem. When utilized as a mask for etching, the photoresist gets irradiated with plasma derived from etching gas or with ion beam for etching. The photoresist irradiated as such changes into a state in which the photoresist cannot be adequately removed with liquid chemicals such as a strong alkali aqueous solution conventionally utilized for a wet etching process.

Therefore, a photoresist processed with dry etching cannot be removed only with a removal solution used in a conventional wet etching process. The photoresist damaged and denatured by dry etching can be removed by an ashing treatment followed by a wet rinsing treatment. Ashing is generally performed with oxygen plasma, and the process of ashing utilizes low molecularization of high molecular resin through a chemical reaction between atomic oxygen and high molecular resin generated in the oxygen plasma, and through decomposition and vaporization of the low molecular resin into CO₂ and H₂O by oxidization of the low molecular resin. Simply put, the process is conceivably based on a chemical reaction represented by CₓH_{y}+O→CO₂+H₂O, wherein CₓH_{y} is a resist film.

At this point, when performing the dry etching, a problem with a ground of the wiring layer arises. A material for the flexible board is an organic film such as polyimide. Therefore, removing of the resist pattern on the wiring layer with the oxygen plasma ashing would also remove the flexible board not covered with the wiring layer at the same time, so that the material for the flexible board itself would disappear.

Hence, it is difficult to perform dry etching on the flexible circuit board as shown in FIG. 6.

The present invention is invented in view of such a conventional problem, and its object is to provide (i) a high-performance flexible circuit board with excellent flexibility, a fine wiring pattern, and fine electric contacts, and (ii) a method for manufacturing the flexible circuit board.

### Solution to Problem

In order to solve the above problem, a flexible circuit board of the present invention includes: a ground board; a semiconductor circuit element positioned on the ground board; a first insulating layer made of an organic material, positioned on the semiconductor circuit element; and a wiring layer made of a conductive material, positioned on the first insulating layer and electrically connected with the semiconductor circuit element through a contact hole, the flexible circuit board further comprising: a second insulating layer made of an inorganic material, positioned between the first insulating layer and the wiring layer.

In order to solve the above problem, a method of the present invention for manufacturing a flexible circuit board includes the steps of: positioning a semiconductor circuit element on a ground board; positioning a first insulating layer made of an organic material on the semiconductor circuit element; positioning a second insulating layer made of an inorganic material on the first insulating layer; forming a contact hole perforating through the first insulating layer and the second insulating layer; and filling the contact hole with a conductive material and positioning a wiring layer on the second insulating layer so as to electrically connect the wiring layer with the semiconductor circuit element.

With the above configuration, the second insulating layer made of an inorganic material is positioned between the wiring layer and the first insulating layer made of an organic material, and the second insulating layer made of an inorganic material is resistant to oxygen plasma. Therefore, it is possible to employ a dry etching method for patterning of the wiring layer and formation of the contact holes, and thus to perform microfabrication in the range of 1-10 μm.

In the flexible circuit board of the present invention, when patterning the wiring layer with dry etching, the first insulating layer made of an organic material is not exposed, but is covered with the second insulating layer made of an inorganic material. Therefore, it is possible, when performing an oxygen plasma treatment to remove a resist subsequent to the dry etching, to remove only the resist on the patterned wiring layer by ashing while preventing the first insulating layer made of an organic material from being removed by ashing.

When forming the contact holes, a resist for formation of the contact holes is patterned on the second insulating layer and then the second insulating layer, which is made of an inorganic material, is subjected to dry etching with the resist as a mask, so that the second insulating layer is perforated. Thereafter, the first insulating layer is subjected to dry etching by oxygen plasma with the second insulating layer perforated by dry etching as a mask, so that contacting portions of the first insulating layer made of an organic material are perforated.

Therefore, when removing the resist pattern of the wiring layer by oxygen plasma ashing in both processes of removing the resist during formation of the wiring layer and of removing the resist during formation of the contact holes, the organic film layer (first insulating layer) not covered with the wiring layer is covered with the inorganic film layer (second insulating layer). Accordingly, it is possible to prevent the flexible board from being removed together with the resist by the oxygen plasma ashing, and to prevent the material for the flexible board itself from disappearing.

Also, while an organic film layer is generally quite flexible, a flexible circuit board itself is easily bendable when even a little force of handling of the board is locally concentrated, so that wiring on the flexible circuit board is at risk of being easily broken. However, as an additional effect of the present invention, providing the inorganic film layer between the wiring layer and the organic film layer improves the rigidity of the flexible circuit board and disperses the force apt to be locally concentrated. This reduces the breakage of the wiring layer.

Furthermore, as another additional effect, the inorganic film layer has the characteristic to function as a gas barrier. Therefore, it is expected that the reliability of the semiconductor element and the passive element below the organic film layer could be improved while the contact holes and the wiring layer can be subjected to dry etching.

### Advantageous Effects of Invention

As described above, with the present invention being configured to position the inorganic film layer between the wiring layer and the organic film layer, it is made possible to (i) prevent breakage of the semiconductor circuit element which is caused when mounting a semiconductor circuit element on a flexible ground board while the semiconductor circuit faces up and then coating the semiconductor circuit element with the organic material to establish wiring and (ii) perform microfabrication within the range of 1-10 μm through employing a dry etching method for patterning of the wiring layer and formation of the contact holes.

Specifically, with the present invention, by positioning an inorganic film layer between a polyimide layer and a metal wiring layer, the inorganic layer protects an organic film layer underneath the wiring layer from being etched during a process of removing a resist subsequent to etching of the wiring layer. Hence, etching on the wiring layer can be performed with dry etching, allowing micropatterning. Also, when forming contact holes, the inorganic film layer can be utilized as a hard mask, thereby enabling processing of the contact holes with dry etching so as to contribute to miniaturization of the contact hole size. Therefore, the present invention enables microfabrication of wiring.

### BRIEF DESCRIPTION OF DRAWINGS

FIG. 1 is a cross-sectional view that schematically shows a flexible circuit board of the present invention.

FIG. 2 is a cross-sectional view that schematically shows the flow of manufacturing the flexible circuit board of the present invention on a glass board.

FIG. 3 is a cross-sectional view that schematically shows the flexible circuit board of the present invention manufactured on the glass board.

FIG. 4 is a cross-sectional view schematically showing separation of the glass board from the flexible circuit board of the present invention through radiating ultraviolet laser.

FIG. 5 is a cross-sectional view that schematically shows a conventional flexible circuit board.

FIG. 6 is a cross-sectional view that schematically shows a conventional flexible circuit board.

### DESCRIPTION OF EMBODIMENTS

Embodiments of the present invention are described in detail below with reference to the drawings. It should be noted that the present invention is not limited to the embodiments, and the sizes, materials, shapes, relative configurations etc. of components illustrated in the embodiments are, unless specified, not to limit the scope of the present invention to only those of the embodiments, and are just examples.

(I) Configuration of Flexible Circuit Board of the Present Invention

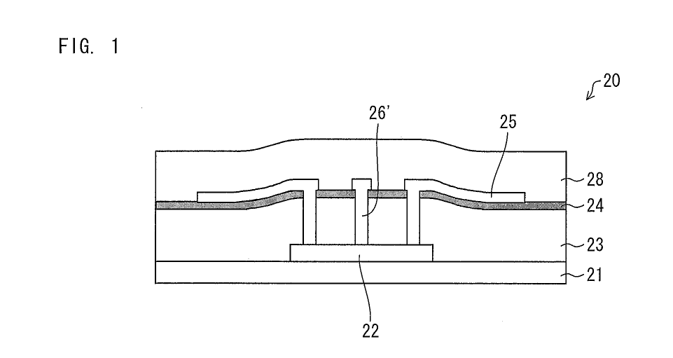

FIG. 1 is a cross-sectional view that schematically shows the configuration of a flexible circuit board of the present invention. As shown in FIG. 1, a flexible circuit board 20 of the present invention includes: a ground board 21; a semiconductor circuit element 22 positioned on a portion of the ground board 21; a first insulating layer 23 made of an organic material, positioned on the semiconductor circuit element 22 and on a portion of the ground board 21, on which portion the semiconductor circuit element 22 is not positioned, in such a manner as to cover the semiconductor circuit element 22; a second insulating layer 24 made of an inorganic material, positioned on the first insulating layer 23; and a wiring layer 25 made of a conductive material, positioned on the second insulating layer 24. The wiring layer 25 and the semiconductor circuit element 22 are electrically connected with each other through a conductive layer 26′ formed by a conductive material filling a contact hole 26.

<Ground Board>

It is desirable that the ground board 21 of the present invention be made of an organic material. The organic material for the ground board 21, for example, includes, but is not particularly limited to, polyimide, polybenzoxazole (PBO), and epoxy. Among the above materials, polyimide has outstanding heat resistance and flexibility, compared to the others. Polyimide's linear expansion coefficient is also remarkably low as an organic material and is close to that of glass and silicon utilized for a ground board. Therefore, when utilized as an insulating material for an electronic circuit, polyimide hardly gets warped due to difference in heat expansion from the board, allowing a wiring process with a high degree of accuracy. Because of such a property, polyimide is a desirable organic material.

The ground board 21 of the present invention is formed on a light transmissive board. Examples of a material for the optically transmissive board include glass, plastic, quartz, and metal foil. Among these materials, glass is desirable because of its high strain point.

<Semiconductor Circuit Element>

The semiconductor circuit element 22 of the present invention is positioned on a portion of the ground board 21. An example of the semiconductor circuit element 22 is an LSI chip.

Also, it is desirable that the semiconductor circuit element 22 of the present invention be formed through the process of getting thinned down. “Getting thinned down” in the present invention indicates reducing a thickness down to approximately 10-50 μm.

<First Insulating Layer>

The first insulating layer 23 of the present invention is positioned on the semiconductor circuit element 22 and on a portion of the ground board 21, on which portion the semiconductor circuit element 22 is not positioned, in such a manner as to cover the semiconductor circuit element 22. Also, the first insulating layer 23 of the present invention is made of an organic material.

The organic material for the first insulating layer 23 of the present invention includes, but is not particularly limited to, polyimide, polybenzoxazole (PBO), and epoxy. Among these organic materials, polyimide is desirable because of its outstanding heat resistance and flexibility.

<Second Insulating Layer>

The second insulating layer 24 of the present invention is positioned on the first insulating layer 23. Also, the second insulating layer 24 of the present invention is made of an inorganic material.

The inorganic material for the second insulating layer 24 includes, but is not particularly limited to, an oxide film and a nitride film. Among them, silicon oxide, silicon nitride, and silicon nitride oxide are materials generally utilized in a current TFT (thin film transistor) process, and are superb in process consistency and sufficiently resistant to ashing. Accordingly, stable films can easily be obtained from these materials through plasma CVD (chemical vapor deposition) etc., making it desirable to arrange the flexible circuit board such that the inorganic material is selected from silicon oxide, silicon nitride, and silicon nitride oxide.

<Wiring Layer>

The wiring layer 25 of the present invention is positioned on the second insulating layer 24. The wiring layer 25 of the present invention is made of a conductive material.

The conductive material is not particularly limited as long as it has such a high-melting point as to allow the conductive material to be resistant to a high-temperature treatment of removal annealing and succeeding recovery annealing. The conductive material includes a metal material such as aluminum, molybdenum, tantalum, tungsten, and copper. A film made of TiN, Ti etc. may be formed as a barrier metal before forming the wiring layer.

Also, it is desirable to arrange the flexible circuit board 20 of the present invention such that the minimum size of a pattern of the wiring layer and the minimum size of the contact holes are in the range of 1-10 μm. Here, the “minimum size” refers to the size of the smallest portions of the pattern of the wiring layer and the contact holes, and it can be said that the smaller the numerical value of the size, the finer the wiring pattern. Besides, it is also desirable that the maximum size of the pattern of the wiring layer and the maximum size of the contact holes be in the range of 10-100 μm.

In addition, the wiring layer 25 of the present invention is not particularly limited as long as it is made of a conductive material. Examples of such wiring include gate wiring, source wiring, and drain wiring.

(II) Method for Manufacturing Flexible Circuit Board of the Present Invention

A method for manufacturing the flexible circuit board of the present invention includes the steps of: positioning a semiconductor circuit element on a ground board made of an organic material (hereinafter referred to as [step 1]); positioning a first insulating layer made of an organic material on the semiconductor circuit element (hereinafter referred to as [step 2]); positioning a second insulating layer made of an inorganic material on the first insulating layer (hereinafter referred to as [step 3]); forming contact holes perforating through the first insulating layer and the second insulating layer (hereinafter referred to as [step 4]); and positioning a wiring layer on the second insulating layer through filling contact holes with a conductive material so as to electrically connect the wiring layer with the semiconductor circuit element (hereinafter referred to as [step 5]).

It is desirable to arrange the method for manufacturing the flexible circuit board of the present invention such that: patterning of the wiring layer and formation of the contact holes are performed with dry etching; the dry etching on the first insulating layer is performed with oxygen-based reactive gas; and the dry etching on the second insulating layer is performed with reactive gas of halogenated carbon including at least one of CF₄, CHF₃, C₃F₈, and CCl₄.

The above steps are described in detail below.

<Step 1>

In the step of positioning the semiconductor circuit element on the ground board made of an organic material, an adhesive is applied to the semiconductor circuit element so as to attach the semiconductor circuit element to the ground board, followed by fixing of the attachment through a heat treatment.

The adhesive to be utilized is not particularly limited as long as it is an organic material, but the same material as utilized for the ground board is preferred. For example, it is desirable to utilize polyimide for the adhesive when the ground board is made of polyimide. Also, the amount of the adhesive to apply is not particularly limited. For example, applying approximately 5-30 μm of the adhesive will accomplish its purpose.

In addition, it is desirable to perform the heat treatment at a temperature that solidifies the adhesive. For example, when utilizing polyimide also as an adhesive, it is desirable to perform the heat treatment in the range of approximately 200-400° C. so as to facilitate imidization, thereby fixing the semiconductor circuit element.

<Step 2>

In the step of positioning the first insulating layer made of an organic material on the semiconductor circuit element, the first insulating layer is formed in such a manner as to cover the semiconductor circuit element attached to the ground board and the portions of the ground board on which the semiconductor circuit element is not attached.

The first insulating layer is formed through application of an organic material, followed by a heat treatment. The amount of the organic material to apply is not particularly limited. For example, applying approximately 30-300 μm of the organic material will accomplish its purpose.

In addition, it is desirable to perform the heat treatment at the temperature that solidifies the organic material. For example, when polyimide is utilized also for the organic material, it is desirable to form the first insulating layer through the heat treatment performed in the range of approximately 200-400° C. so as to facilitate imidization.

<Step 3>

In the step of positioning the second insulating layer made of an inorganic material on the first insulating layer, the second insulating layer made of an inorganic material is formed on the first insulating layer made of an organic material.

In so doing, plasma CVD is to be employed, for example. The thickness of the inorganic material is not particularly limited. For example, applying approximately 30-300 μm of the inorganic material will accomplish its purpose.

Also, reactive gas to be utilized in the case of employing the plasma CVD is not particularly limited, although [SiH₄+O₂]-based or TEOS (tetraethoxysilane)-based gas is normally utilized when silicon oxide is utilized as the inorganic material, and [SiH₄+NH₃]-based, [SiH₄+N₂O]-based, or [SiH₄+NO]-based gas is normally utilized when silicon nitride or silicon nitride oxide is utilized as the inorganic material.

Furthermore, when employing the plasma CVD, setting the temperature to the range of approximately 300-500° C. will accomplish its purpose.

<Step 4>

First, the step of forming the contact holes perforating through the second insulating layer is described below.

In the step of forming the contact holes perforating through the second insulating layer, the contact holes are formed at predetermined positions on the second insulating layer in order to electrically connect the wiring layer, which is to be formed in a later step, with the semiconductor circuit element. To begin with, a resist is applied to the second insulating layer, and the second insulating layer is subjected to exposure and development. In order to miniaturize the wiring pattern and the contact holes, the same processing employed to form a conventional and well-known TFT is to be employed on a glass board, thereby making it possible to form a fine photo pattern of 10 μm or less in size.

Then, by performing plasma dry etching with the resist as a mask, the contact holes can be made at the predetermined positions on the second insulating layer.

Although reactive gas to be utilized for the plasma dry etching is not particularly limited, it is desirable to utilize, for example, halogenated carbon such as CF₄, CHF₃, C₃F₈, and CCl₄ etc., and to compound the halogenated carbon with O₂, H₂, N₂, He, and Aᵣ etc. in order to enhance the speed of the etching and to increase a selection ratio etc.

Also, setting the pressure needed to perform the plasma dry etching to the range of approximately 0.1-100 pa, and setting the microwave output to the range of approximately 100-1000 W will accomplish its purpose.

Next, the step of forming the contact holes perforating through the first insulating layer is described below.

In the step of forming the contact holes perforating through the first insulating layer, the contact holes are formed at predetermined positions on the first insulating layer to connect the wiring layer (which is to be formed in a later step) with the semiconductor circuit element.

In so doing, etching of the first insulating layer is performed through plasma dry etching with the entire second insulating layer except the portions on which the contact holes were formed in the previous step (the step of forming the contact holes perforating through the second insulating layer) as a mask, so that the contact holes to connect the wiring layer with the semiconductor circuit element are formed. At this point, the resist gets removed during the etching of the first insulating layer. Besides, portions of the first insulating layer which are covered with the second insulating layer even after formation of the contact holes perforating through the second insulating layer do not disappear during the etching because the portions of the first insulating layer are protected by the second insulating layer.

Although reactive gas for the plasma dry etching is not particularly limited, it is desirable to utilize O₂-based gas, and to add a little amount of CF₄ in order to enhance the speed of the etching. At this point, the plasma dry etching can be performed with the O₂-based reactive gas because the second insulating layer is made of an inorganic material and is resistant to oxygen plasma.

Also, setting the pressure needed to perform the plasma dry etching to the range of approximately 0.1-10 pa, and setting the microwave output to the range of approximately 100-1000 W will accomplish its purpose.

<Step 5>

In the step of positioning the wiring layer on the second insulating layer, the contact holes are filled with a conductive material so as to form conductive layers, and then the wiring layer is formed on the conductive layers and on the second insulating layer and is patterned. A method for forming the wiring layer is not particularly limited. Examples of the method include CVD and sputtering.

Subsequently, the wiring layer formed is patterned with dry etching. Here, the wiring layer can be patterned with dry etching because the second insulating layer is made of an inorganic material, and is resistant to oxygen plasma.

The flexible circuit board manufactured through the above steps does not suffer an adverse effect on the organic film layer below the wiring when subjected to a dry etching process for example, and exhibits outstanding flexibility and realizes microfabrication of the wiring.

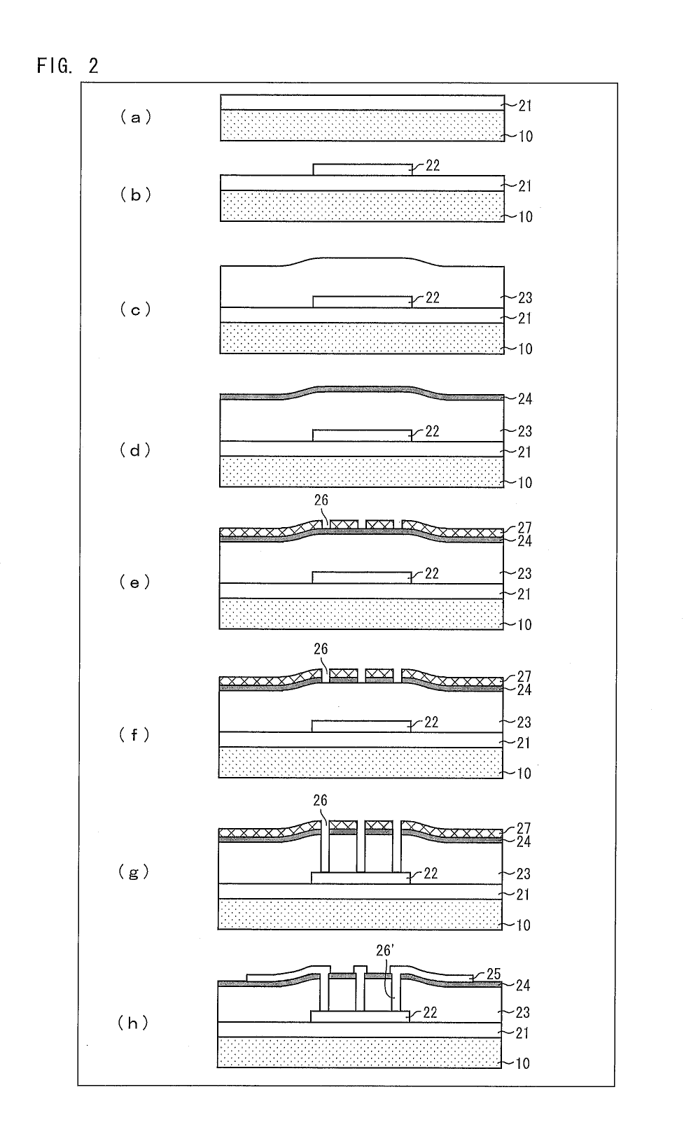

With reference to FIG. 2, the flow of the manufacturing of the flexible circuit board 20 in FIG. 1 is described below as a specific example.

First, as shown in (a) of FIG. 2, an alkali-free glass board 10 is prepared as a glass board for a display. The glass board 10 has the linear expansion coefficient of about 4×10⁻⁶/K, and the glass transition temperature of 400° C. or higher, and so the glass board 10 is highly heat resistant. Further, a ground board 21 is formed by applying polyimide to the glass board 10.

The polyimide film layer, which is to be the ground board 21, is formed, for example, through (i) coating the glass board with PI2610 manufactured by Hitachi Chemical DePont MicroSystems, LLC., utilizing a spin coating technique or a slit coating technique, and (ii) performing a heat treatment on the product at the temperature of 200-400° C., thereby vaporizing an organic solvent so as to facilitate imidization.

Here, the PI2610 is a liquid with 2.8 Pa·S viscosity containing, in an organic solvent N-methyl-2-pyrrolidone, 10-30% of S-biphenyl dianhydride/phenylenediamine polymer which is a precursor of polyimide. The thickness of the PI2610 coating is to be about 30-300 μm. Also, the linear expansion coefficient of PI2610 is approximately 5×10⁻⁶/K being substantially equal to that of the glass substrate 10. This is advantageous because the glass substrate exhibits only small expansion and contraction and PI2610 can easily follow the expansion and contraction. An adequate material for the polyimide to be applied may be selected depending on the subsequent process of the heat treatment, the linear expansion coefficient of the board, and transparency of the polyimide film layer etc.

Then, as shown in (b) of FIG. 2, the thinned-down semiconductor circuit element 22 such as an LSI is mounted on and then attached to the ground board 21. The semiconductor circuit element 22 is about 10-50 μm in thickness, and is attached to the ground board 22 after polishing the backside etc of the semiconductor circuit element 22. More specifically, the attachment is performed through (i) the polyimide about 5-30 μm in thickness being applied to the semiconductor circuit element 22 as an adhesive prior to the attachment, and (ii) a heat treatment at the temperature of about 200-400° C. being conducted to facilitate imidization, thereby fixing the attachment.

Then, in order to ensure insulation of the semiconductor circuit element 22 as well as flattening the surface of the board, the first insulating layer (organic film layer) 23 is, as shown in (c) of FIG. 2, formed in such a manner as to cover the semiconductor circuit element 22 attached to the ground board and the portions of the ground board 21 to which portions the semiconductor circuit element 22 is not attached. The first insulating layer 23 is formed through (i) the polyimide about 30-300 μm in thickness being applied to the board, and (ii) a heat treatment at the temperature of about 200-400° C. being conducted to facilitate imidization.

Subsequently, as shown in (d) of FIG. 2, the second insulating layer (inorganic film layer) 24 made of an inorganic material and being about 30-300 nm in thickness is formed on the first insulating layer 23 made of an organic material such as polyimide. The second insulating layer 24 can be made of silicon oxide, silicon nitride, and silicon nitride oxide etc. by plasma CVD etc.

At this point, in the case of forming the second insulating layer 24 of silicon oxide, utilizing [SiH₄+O₂]-based or TEOS (tetraethoxysilane)-based gas as reactive gas, and setting the temperature to the range of approximately 300-500° C. will accomplish its purpose. Further, in the case of forming the second insulating layer 24 of silicon nitride or silicon nitride oxide, utilizing [SiH₄+NH₃]-based, [SiH₄+N₂O]-based, or [SiH₄+NO]-based gas as reactive gas, and setting the temperature to the range of approximately 300-500° C. will accomplish its purpose.

Next, in order to electrically connect the wiring layer 25, which is to be formed in a later step, with the semiconductor circuit element 22, the contact holes 26 are formed at the predetermined positions on the first insulating layer 23 and the second insulating layer 24. To begin with, as shown in (e) of FIG. 2, a resist 27 is applied to the second insulating layer 24, and the second insulating layer 24 is exposed and developed. In order to design a fine pattern, the same processing employed to form a TFT is to be employed on the glass board, thereby making it possible to form a fine photo pattern of less than 10 μm in size.

Then, as shown in (f) of FIG. 2, the contact holes 26 are formed at the predetermined positions on the second insulating layer 24 by plasma dry etching with the resist 27 as a mask. Halogenated carbon such as CF₄, CHF₃, C₃F₈, and CCl₄ are to be utilized as reactive gas for the plasma dry etching, and O₂, H₂, N₂, He, and Aᵣ etc can be compounded with the halogenated carbon in order to enhance the speed of the etching and to increase a selection ratio. Besides, when performing the plasma dry etching, the pressure is to be set to the range of approximately 0.1-100 pa, and the microwave output is to be set to the range of appropriately 100-1000 W.

Next, as shown in (g) of FIG. 2, the contact holes to connect the wiring layer 25 with the semiconductor circuit element 22 are made at predetermined positions of the first insulating layer 23. The contact holes to connect the wiring layer 25 with the semiconductor circuit element 22 are formed through (i) etching the first insulating layer 23 by plasma dry etching with O₂-based reactive gas, and (ii) utilizing the entire second insulating layer 24 as a mask except the portions at which the contact holes were made in the previous step. The plasma dry etching can be performed with the O₂-based reactive gas because, as mentioned above, the second insulating layer 24 is made of an inorganic material and is resistant to oxygen plasma.

At this point, the resist 27 gets removed during the etching of the first insulating layer 23. Besides, as shown in (f) of FIG. 2, portions of the first insulating layer 23 which are covered with the second insulating layer 24 even after formation of the contact holes 26 perforating through the second insulating layer 24 do not disappear during the dry etching because the portions of the first insulating layer 23 are protected by the second insulating layer 24. Also, when performing the plasma dry etching, the pressure is to be set to the range of approximately 0.1-10 pa, and the microwave output is to be set to the range of approximately 100-1000 W. Furthermore, a little amount of CF₄ can be added as reactive gas in order to enhance the speed of the etching.

In this way, the contact holes electrically connecting the wiring layer 25 and the semiconductor circuit element 22 can be formed by the dry etching, thereby enabling microfabrication in the order of 10 μm or less.

Next, as shown in (h) of FIG. 2, the conductive layers 26′ are formed through filling the contact holes 26 with a conductive material, and thereafter the wiring layer 25 is formed on the conductive layers 26′ and on the second insulating layer 24 followed by the patterning of the wiring layer 25. The wiring layer 25 is formed by CVD or sputtering. Examples of the conductive material include metal materials such as aluminum, molybdenum, tantalum, tungsten, and copper. A film made of TiN, Ti etc. may be formed as a barrier metal before forming the wiring layer.

Subsequently, as shown in (h) of FIG. 2, the wiring layer 25 is patterned. In this process, too, because the second insulating layer 24 (inorganic film layer) is positioned below the wiring layer 25, the wiring layer 25 can be patterned through dry etching, thereby allowing microfabrication of the wiring layer. That is, micropatterning in the order of 10 μm or less is possible.

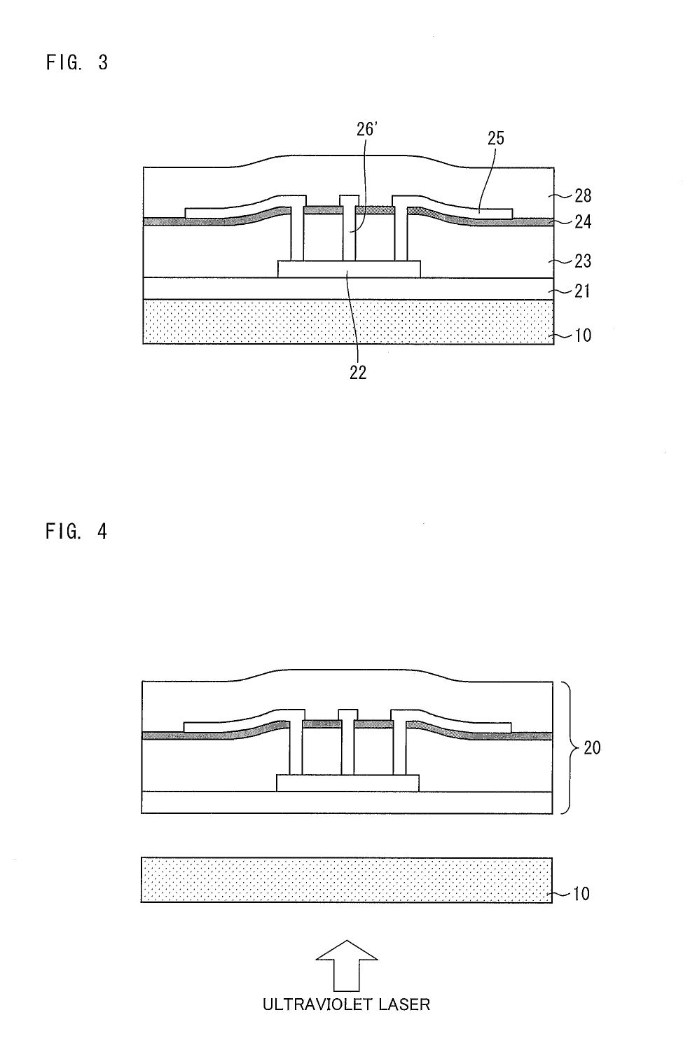

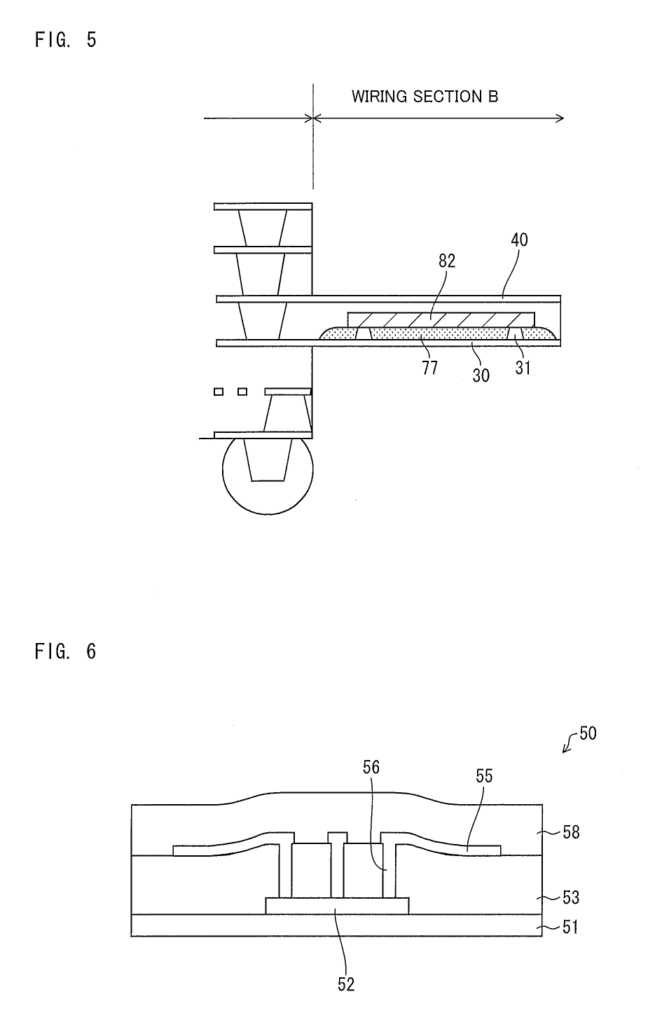

At this point, in order to protect the wiring layer 25, a protective layer 28 can be additionally formed on the wiring layer 25 as shown in FIG. 3. For example, the protective layer (organic film layer) 28 can be formed through coating the wiring layer 25 with polyimide of approximately 30-300 μm thickness by spin coating or slit coating, followed by imidization by a heat treatment at the temperature of approximately 200-400° C.

Lastly, as shown in FIG. 4, the glass board 10 gets separated from the ground board 21 by being irradiated with ultraviolet laser from the backside of the glass board 10. Specifically, the ultraviolet is absorbed at and around the surface of the ground board 21 at which surface the ground board 21 contacts the glass board 10, so as to partially decompose and remove (ablate) the ground board 21 made of the polyimide, thereby causing a separation between the glass board 10 and the ground board 21. This is how the flexible circuit board 20 as shown in FIG. 1 is manufactured.

Besides, the ultraviolet to be radiated may be light having a wavelength that enables the light to be transmitted through the glass board 10 and absorbed by the ground board 21, such as excimer laser (of 308 nm in wavelength) whose radiant energy is 100-300 mJ/cm². Because the radiation time (pulse width) of the light is extremely short as less than 1 μsec, an increase in temperature of the semiconductor circuit element 22 provided on the ground board 21 is small, thereby causing no adverse effect on the semiconductor circuit element 22.

With the configuration and the method above, it is possible to provide a flexible circuit board (i) having excellent flexibility, a fine wiring pattern, and fine electric contacts, and (ii) including a high-performance thin film semiconductor circuit element.

The present invention can also be described as follows.

The flexible circuit board of the present invention is designed such that the minimum size of a pattern of the wiring layer and the minimum size of the contact hole are in the range of 1-10 μm.

With the above configuration, the minimum size, which has been conventionally several dozens of μm, can be miniaturized to the range of 1-10 μm, thereby achieving high-density mounting of a passive element and a semiconductor circuit element.

Additionally, the flexible circuit board of the present invention is designed such that the inorganic material is selected from silicon oxide, silicon nitride and silicon nitride oxide.

With the above configuration, the inorganic material has high insulation property and barrier property and can be accumulated at a low temperature without being damaged by plasma, thereby being effective as a protective layer.

Also, the flexible circuit board of the present invention is designed such that the organic material is polyimide.

Polyimide has outstanding heat resistance and insulation property, and polyimide's linear expansion coefficient is also remarkably low as an organic material and is close to that of glass and silicon utilized for a board. Therefore, with the above configuration, when utilized as an insulating material for an electronic circuit, polyimide hardly gets warped by a difference in heat expansion from the board, thereby making it possible to perform a wiring process with a high degree of accuracy. In addition, bending of the board by physical stress is unlikely to occur, thereby increasing productivity.

Also, the method of the present invention for manufacturing a flexible circuit board is designed such that patterning of the wiring layer and formation of the contact hole are performed with dry etching.

Also, the method of the present invention for manufacturing a flexible circuit board is designed such that the dry etching on the first insulating layer is performed with oxygen-based reactive gas.

With the above configuration, the dry etching can be performed with oxygen plasma, and removal of the resist and formation of the contact hole perforating through the organic film layer (first insulating layer) can be performed simultaneously.

Also, the method of the present invention for manufacturing a flexible circuit board is designed such that the dry etching on the second insulating layer is performed with reactive gas of halogenated carbon including at least one selected from CF₄, CHF₃, C₃F₈, and CCl₄.

With the above configuration, fluorine radical and/or chlorine radical react with silicon (Si) in an oxide film or nitride film, and produce a reaction product such as SiF₄ and SiCCl₃ with high volatility. This is how the etching can be effectively progressed.

The present invention is not limited to the description of the embodiments above, but may be altered by a skilled person within the scope of the claims. An embodiment based on a proper combination of technical means disclosed in different embodiments is encompassed in the technical scope of the present invention.

### INDUSTRIAL APPLICABILITY

The present invention is applicable to a semiconductor device, a display device such as a liquid crystal display and an organic EL display, and a wearable device etc.

### REFERENCE SIGNS LIST

10 Glass board
20 Flexible circuit board
21 Ground board
22 Semiconductor circuit element
23 First insulating layer (organic film layer)
24 Second insulating layer (inorganic film layer)
25 Wiring layer
26 Contact holes
26′ Conductive layer
27 Resist
28 Protective layer

1. A flexible circuit board comprising:
a ground board;
a semiconductor circuit element positioned on the ground board;
a first insulating layer made of an organic material, positioned on the semiconductor circuit element; and
a wiring layer made of a conductive material, positioned on the first insulating layer and electrically connected with the semiconductor circuit element through a contact hole,
the flexible circuit board further comprising:
a second insulating layer made of an inorganic material, positioned between the first insulating layer and the wiring layer.

2. The flexible circuit board as set forth in claim 1, wherein the minimum size of a pattern of the wiring layer and the minimum size of the contact hole are in a range of 1-10 μm.

3. The flexible circuit board as set forth in claim 1, wherein the inorganic material is selected from silicon oxide, silicon nitride and silicon nitride oxide.

4. A flexible circuit board as set forth in claim 1, wherein the organic material is polyimide.

5. A method for manufacturing a flexible circuit board, comprising the steps of:
positioning a semiconductor circuit element on a ground board;
positioning a first insulating layer made of an organic material on the semiconductor circuit element;
positioning a second insulating layer made of an inorganic material on the first insulating layer;
forming a contact hole perforating through the first insulating layer and the second insulating layer; and
filling the contact hole with a conductive material and positioning a wiring layer on the second insulating layer so as to electrically connect the wiring layer with the semiconductor circuit element.

6. The method as set forth in claim 5, wherein patterning of the wiring layer and formation of the contact hole are performed with dry etching.

7. The method as set forth in claim 6, wherein the dry etching on the first insulating layer is performed with oxygen-based reactive gas.

8. The method as set forth in claim 6, wherein the dry etching on the second insulating layer is performed with reactive gas of halogenated carbon including at least one selected from CF₄, CHF₃, C₃F₈, and CCl₄.
